(19) United States
(12) Patent Application Publication
(10) Pub. No.: US 2022/0301739 A1
(43) Pub. Date: Sep. 22, 2022

(54) OPTICALLY CONSISTENT TRANSPARENT CONDUCTOR AND MANUFACTURING METHOD THEREOF

(71) Applicant: Cambrios Film Solutions Corporation, Tortola (VG)

(72) Inventors: Shih-Ching Chen, New Taipei City (TW); Wei-Chia Fang, Hsinchu County (TW); En-Chia Chang, Taipei City (TW); Wei-Cheng Hsu, New Taipei City (TW); Chung-Chin Hsiao, Hsinchu County (TW)

(21) Appl. No.: 17/203,217

(22) Filed: Mar. 16, 2021

(51) Int. Cl. H01B 7/00

(52) U.S. Cl. CPC H01B 7/00

(57) ABSTRACT

An optically consistent transparent conductor includes a first region and a second region. The first region includes a plurality of nanostructures. The first region has a first electrical resistivity and a first haze. The second region has a second electrical resistivity and a second haze. A difference in ratio between the first electrical resistivity and the second electrical resistivity is in a range from 5% to 9900%, and a difference in ratio between the first haze and the second haze is in a range from 2% to 500%.

### BACKGROUND

### Field of Disclosure

The disclosure relates to an optically consistent transparent conductor and a manufacturing method thereof.

### Description of Related Art

Transparent conductive films with high conductivity and transparency are widely used in fields of displays, touch panels, electrostatic shielding, anti-reflective coatings, etc. In the foregoing fields, indium tin oxide (ITO) is often used as a material of a transparent conductive film because of its low electrical resistivity and high light transmittance. In recent years, metal nanowires are also often used as materials of transparent conductive films.

At present, a common method for manufacturing a transparent conductive film includes uniformly coating a substrate with ink including metal nanowires, and simultaneously forming a circuit pattern in a functional region and a dummy pattern in a non-functional region through lithography and etching process. In the patent entitled “NANOWIRE-BASED TRANSPARENT CONDUCTOR AND METHOD OF PATTERNING THE SAME” (Patent Publication Number CN102834936B) and the patent entitled “CONDUCTIVE FILM WITH LOW VISIBILITY PATTERN AND PREPARATION METHOD THEREOF” (Patent Publication Number CN104969303B), a circuit pattern in a functional region and a dummy pattern in a non-functional region are simultaneously formed through a subtractive process of one-time coating and one-time lithography and etching. However, it is difficult to finely control local optical properties in the operation of the lithography and etching process, so it easily leads to the shortcoming of inconsistent local optical properties. On the other hand, the foregoing method easily makes the circuit pattern in the functional region and the dummy pattern in the non-functional region mutually restrained in electrical and optical properties, making it difficult to meet users' requirements.

### SUMMARY

The disclosure relates in general to an optically consistent transparent conductor and a manufacturing method thereof.

According to some embodiments of the present disclosure, the optically consistent transparent conductor includes a first region and a second region. The first region includes a plurality of nanostructures. The first region has a first electrical resistivity and a first haze. The second region has a second electrical resistivity and a second haze. A difference in ratio between the first electrical resistivity and the second electrical resistivity is in a range from 5% to 9900%, and a difference in ratio between the first haze and the second haze is in a range from 2% to 500%.

In some embodiments of the present disclosure, the difference in ratio between the first electrical resistivity and the second electrical resistivity is in a range from 5% to 5000%.

In some embodiments of the present disclosure, the first region has a first light transmittance, the second region has a second light transmittance, and a difference in ratio between the first light transmittance and the second light transmittance is in a range from 0.1% to 15%.

In some embodiments of the present disclosure, the first region has a first yellowness, the second region has a second yellowness, and a difference in ratio between the first yellowness and the second yellowness is in a range from 1% to 700%.

In some embodiments of the present disclosure, the nanostructures are metal nanowires.

In some embodiments of the present disclosure, the second region includes a plurality of doped structures, and the doped structures include metal nanowires, carbon nanotubes, graphene, poly(3,4-ethylenedioxythiophene), or combinations thereof.

In some embodiments of the present disclosure, a load capacity of the nanostructures per unit area in the first region is greater than a load capacity of the doped structures per unit area in the second region.

In some embodiments of the present disclosure, the second region includes at least one dummy structure.

In some embodiments of the present disclosure, the first region has a width between 2 μm and 50 mm, and the second region has a width between 2 μm and 50 mm.

In some embodiments of the present disclosure, the first region has a thickness between 10 nm and 10 μm, and the second region has a thickness between 10 nm and 10 μm.

In some embodiments of the present disclosure, the optically consistent transparent conductor further includes at least one protective layer covering the first region and the second region, in which the protective layer includes an insulating material.

In some embodiments of the present disclosure, the protective layer has a thickness between 0.1 μm and 10 μm.

In some embodiments of the present disclosure, the optically consistent transparent conductor further includes a substrate carrying the first region and the second region, in which the substrate includes polyethylene terephthalate, cycloolefin polymer, polyimide, or combinations thereof.

In some embodiments of the present disclosure, the substrate has a thickness between 15 μm and 150 μm.

In some embodiments of the present disclosure, the first region is located on a first horizontal plane, the second region is located on a second horizontal plane, and the first horizontal plane is different from the second horizontal plane.

In some embodiments of the present disclosure, an overlapping area of the first region and the second region in a vertical direction is less than or equal to 50% of an area of the first region, and the vertical direction is perpendicular to the first horizontal plane and the second horizontal plane.

According to some embodiments of the present disclosure, the method for manufacturing an optically consistent transparent conductor includes the following steps: coating a substrate to form a first region including a plurality of nanostructures, in which the first region has a first electrical resistivity and a first haze; and coating the substrate to form a second region, in which the second region has a second electrical resistivity and a second haze, a difference in ratio between the first electrical resistivity and the second electrical resistivity is in a range from 5% to 9900%, and a difference in ratio between the first haze and the second haze is in a range from 2% to 500%.

In some embodiments of the present disclosure, coating the substrate to form the first region including the nanostructures includes: coating the substrate with a first solution, in which the first solution has a viscosity between 50 cp and 2000 cp, and based on a total weight of the first solution, the first solution has a solid content between 0.01 wt % and 2.00 wt %.

In some embodiments of the present disclosure, coating the substrate to form the second region includes: coating a substrate with a second solution, in which the second solution has a viscosity between 50 cp and 2000 cp, and based on a total weight of the second solution, the second solution has a solid content between 0.01 wt % and 2.00 wt %.

In some embodiments of the present disclosure, coating the substrate to form the first region including the nanostructures includes forming the first region on a first horizontal plane, coating the substrate to form the second region includes forming the second region on a second horizontal plane, and the first horizontal plane is different from the second horizontal plane.

According to the aforementioned embodiments of the present disclosure, since the optically consistent transparent conductor of the present disclosure is coated multiple times to respectively form a functional region (e.g., the first region) and a non-functional region (e.g., the second region) therein, the functional region and the non-functional region can respectively have different materials and load capacities, so as to respectively provide suitable electrical and optical properties. As such, the electrical and optical properties of the functional region and the non-functional region can be adjusted separately according to the requirements of the product, such that the two regions can have a quite consistent optical performance while having different electrical performances.

### BRIEF DESCRIPTION OF THE DRAWINGS

The disclosure can be more fully understood by reading the following detailed description of the embodiments, with reference made to the accompanying drawings as follows:

FIG. 1A is a schematic top view illustrating an optically consistent transparent conductor according to some embodiments of the disclosure;

FIG. 1B is a schematic cross-sectional view illustrating the optically consistent transparent conductor of FIG. 1A along line a-a′;

FIG. 2 is a schematic cross-sectional view illustrating an optically consistent transparent conductor according to some other embodiments of the disclosure;

FIG. 3 is a schematic cross-sectional view illustrating an optically consistent transparent conductor according to some other embodiments of the disclosure;

FIG. 4 shows a schematic cross-sectional view illustrating an optically consistent transparent conductor according to some other embodiments of the disclosure;

FIGS. 5A to 5I are schematic cross-sectional views illustrating a method for manufacturing the optically consistent transparent conductor of FIG. 1B at different steps;

FIGS. 6A to 6D are schematic cross-sectional views illustrating a method for manufacturing the optically consistent transparent conductor of FIG. 2 at different steps;

FIGS. 7A to 7I are schematic cross-sectional views illustrating a method for manufacturing the optically consistent transparent conductor of FIG. 3 at different steps; and

FIGS. 8A to 8D are schematic cross-sectional views illustrating a method for manufacturing the optically consistent transparent conductor of FIG. 4 at different steps.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In addition, relative terms such as “lower” or “bottom” and “upper” or “top” can be used herein to describe the relationship between one component and another, as shown in the figures. It should be understood that the relative terms are intended to include different orientations of the device other than those shown in the figures. For example, if the device in accompanying drawings is turned upside down, a component described as being on the “lower” side of another component will be oriented on the “upper” side of another component. Therefore, the exemplary term “lower” may include the orientations of “lower” and “upper”, depending on the specific orientation of the accompanying drawing. Similarly, if the device in an accompanying drawing is turned upside down, a component described as “below” another component will be oriented as being “above” another component. Therefore, the exemplary term “below” may include upper and lower orientations.

The disclosure provides an optically consistent transparent conductor and a manufacturing method thereof. The optically consistent transparent conductor can be applied to a display device such as a touch panel. In the process of manufacturing the optically consistent transparent conductor, a functional region and a non-functional region are formed respectively by coating multiple times, such that the functional region and the non-functional region can respectively have different materials and load capacities, so as to respectively provide suitable electrical and optical properties. As such, the electrical and optical properties of the functional region and the non-functional region can be adjusted separately according to the needs of the product, such that the two regions can have a quite consistent optical performance while having different electrical performances.

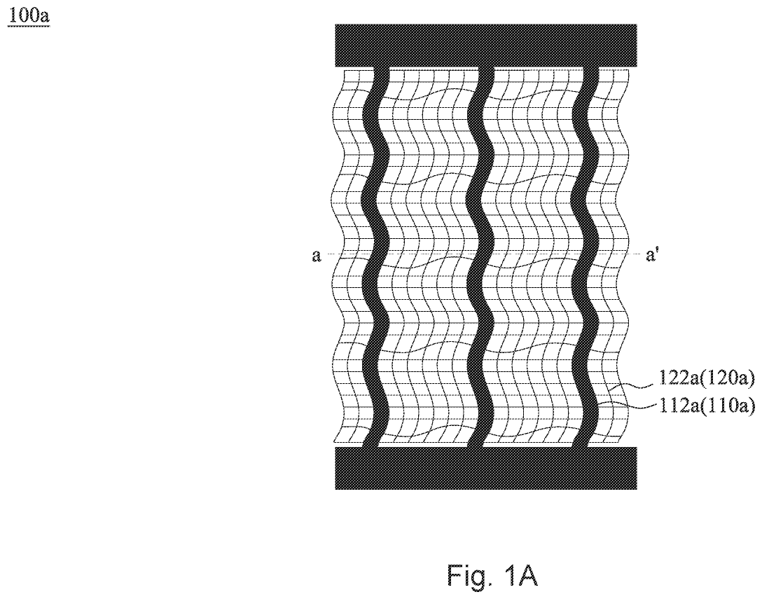

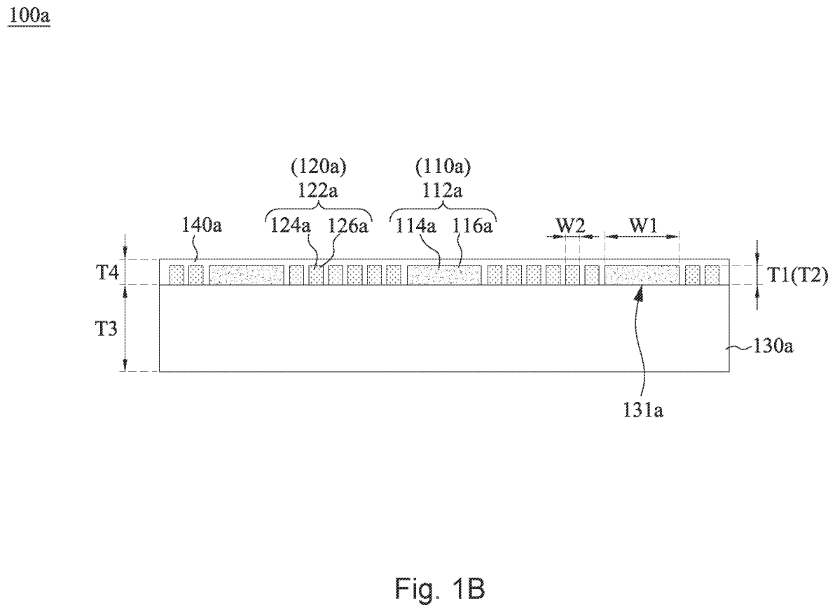

FIG. 1A is a schematic top view illustrating an optically consistent transparent conductor 100a according to some embodiments of the disclosure. FIG. 1B is a schematic cross-sectional view illustrating the optically consistent transparent conductor 100a of FIG. 1A along line a-a′. Please refer to FIG. 1A and FIG. 1B. The optically consistent transparent conductor 100a includes at least one functional region (also referred to as a first region) 110a and at least one non-functional region (also referred to as a second region) 120a. The functional region 110a has electrical functions (e.g., has touch sensing and signal transmission functions), while the non-functional region 120a has no electrical functions (e.g., has no touch sensing and signal transmission functions) but may have optical auxiliary functions (e.g., making the optically consistent transparent conductor 100a have a more consistent optical performance and reducing the generation of bright and dark blocks). In some embodiments, when the optically consistent transparent conductor 100a is disposed in a touch panel, both the functional region 110a and the non-functional region 120a are located in a visible region of the touch panel. In some embodiments, the functional region 110a and the non-functional region 120a may be adjacently arranged on the same horizontal plane. In some other embodiments, a plurality of functional regions 110a and a plurality of non-functional regions 120a may be arranged in a staggered or array manner on the same horizontal plane.

In some embodiments, the functional region 110a may include a conductive layer 112a, and the conductive layer 112a may be patterned to form a circuit pattern with electrical functions (e.g., touch sensing and signal transmission functions). In some embodiments, the conductive layer 112a of the functional region 110a may include a matrix 114a and a plurality of metal nanowires (also referred to as metal nanostructures) 116a distributed in the matrix 114a. In some embodiments, the matrix 114a may be, for example, an optically transparent material, that is, its light transmittance in a visible region (with a wavelength of 400 nm to 700 nm) may be at least greater than 80%, so as to provide the conductive layer 112a with good light transmittance. In some embodiments, the matrix 114a may include polymers or a mixture thereof to impart specific chemical, mechanical, and optical properties to the conductive layer 112a. For example, the matrix 114a may provide adhesion between the conductive layer 112a and other layers (e.g., a substrate 130a configured to carry the functional region 110a and the non-functional region 120a). For another example, the matrix 114a can also provide the conductive layer 112a with good mechanical strength. In some embodiments, the matrix 114a may also include a specific polymer, such that the metal nanowires 116a have additional scratch/wear-resistant surface protection, thereby improving the surface strength of the conductive layer 112a. The foregoing specific polymer may be, for example, polyacrylate, epoxy resin, polyurethane, polysiloxane, polysilane, poly(silicon-acrylic acid), or combinations thereof. In some embodiments, the matrix 114a may further include a cross-linking agent, a stabilizer (e.g., including but not limited to an antioxidant or an ultraviolet stabilizer), a polymerization inhibitor, a surfactant, or combinations thereof, so as to improve the ultraviolet resistance of the conductive layer 112a and prolong a service life of the conductive layer 112a.

In some embodiments, the metal nanowires 116a may include, but are not limited to, silver nanowires, gold nanowires, copper nanowires, nickel nanowires, or combinations thereof. More specifically, the “metal nanowires 116a” herein is a collective noun, which refers to a collection of metal wires of a plurality of metal elements, metal alloys, or metal compounds (including metal oxides). In some embodiments, a cross-sectional size of a single metal nanowire 116a (i.e., a diameter of the cross-section) may be less than 500 nm, preferably less than 100 nm, and more preferably less than 50 nm, such that the conductive layer 112a has lower haze. In detail, when the cross-sectional size of the single metal nanowire 116a is greater than 500 nm, the single metal nanowire 116a is excessively thick, resulting in excessively high haze of the conductive layer 112a, thus affecting the visual clarity of the functional region 110a. In some embodiments, an aspect ratio (length to diameter) of the single metal nanowire 116a may be between 10 and 100,000, such that the conductive layer 112a may have lower electrical resistivity, higher light transmittance, and lower haze. In detail, when the aspect ratio of a single metal nanowire 116a is less than 10, a conductive network may not be well formed, resulting in excessively high electrical resistivity of the conductive layer 112a. Therefore, the metal nanowires 116a must be distributed in the matrix 114a with a greater arrangement density (i.e., the number of metal nanowires 116a included in the conductive layer 112a per unit volume) in order to improve the conductivity of the conductive layer 112a, such that the conductive layer 112a has excessively low light transmittance and excessively high haze. It should be understood that other terms, such as silk, fiber, or tube can also have the foregoing cross-sectional sizes and aspect ratios, which are also covered by the present disclosure. It should be noted that the “electrical resistivity” of a certain layer mentioned in this disclosure refers to the “sheet resistance” (unit: Ohms per square (ops)) of the layer.

In some embodiments, a load capacity of the metal nanowires 116a per unit area in the conductive layer 112a may be between 0.05 μg/cm² and 10 μg/cm², such that the conductive layer 112a can have lower electrical resistivity, higher light transmittance, and lower haze. In detail, when the load capacity of the metal nanowires 116a per unit area in the conductive layer 112a is less than 0.05 μg/cm², it may cause the metal nanowires 116a to fail to be in contact with each other in the matrix 114a to provide a continuous current path, such that the electrical resistivity of the conductive layer 112a is excessively high and the electrical conductivity of the conductive layer 112a is excessively low; when the load capacity of the metal nanowires 116a per unit area in the functional region 110a is greater than 10 μg/cm², it may cause the conductive layer 112a to have excessively low light transmittance and excessively high haze, thus affecting the optical properties of the functional region 110a (e.g., the functional region 110a may not have good optical transparency and clarity).

The conductive layer 112a of the present disclosure may have suitable electrical resistivity, light transmittance, and haze, in which the electrical resistivity, light transmittance, and haze of the conductive layer 112a can be respectively regarded as the electrical resistivity, light transmittance, and haze of the functional region 110a, and can be respectively referred to as the first electrical resistivity, the first light transmittance, and the first haze in the present disclosure. In some embodiments, the electrical resistivity of the conductive layer 112a may be less than 200 ops, such that the functional region 110a has better conductivity. In some embodiments, the light transmittance of the conductive layer 112a may be greater than 80%, such that the functional region 110a has better optical transparency. In some embodiments, the haze of the conductive layer 112a may be less than 3%, such that the functional region 110a has better optical clarity. It is understood that the light transmittance of the conductive layer 112a refers to a luminous flux percentage of visible light (light with a wavelength between 400 nm and 700 nm) passing through the conductive layer 112a to visible light incident on the conductive layer 112a, while the haze of the conductive layer 112a refers to a luminous flux percentage of visible light scattered after being incident on the conductive layer 112a to visible light incident on the conductive layer 112a.

In some embodiments, the non-functional region 120a includes a dummy layer 122a, and the dummy layer 122a may be patterned to form a dummy pattern with an optical auxiliary function. The dummy layer 122a in the non-functional region 120a is configured such that the non-functional region 120a and the functional region 110a can have a consistent optical performance. In some embodiments, the dummy layer 122a may be, for example, one or more dummy structures connected or disconnected with each other. In some embodiments, the dummy layer 122a may include a matrix 124a that is substantially the same as the foregoing matrix 114a. In some embodiments, the dummy layer 122a may further include a plurality of doped structures 126a distributed in the matrix 124a, and the doped structures 126a may include, but are not limited to, metal nanowires, carbon nanotubes, graphene, poly(3,4-ethylenedioxythiophene), or combinations thereof.

In some embodiments, a load capacity of the doped structures 126a per unit area in the dummy layer 122a may be between 0.05 μg/cm² and 10 μg/cm², so as to ensure that the non-functional region 120a and the functional region 110a can have a consistent optical performance. In detail, when the load capacity of the doped structures 126a per unit area in the dummy layer 122a is less than 0.05 μg/cm², it may lead to a great difference between optical properties of the dummy layer 122a and the conductive layer 112a, such that the non-functional region 120a and the functional region 110a cannot have a consistent optical performance; when the load capacity of the doped structures 126a per unit area in the dummy layer 122a is greater than 10 μg/cm², it may make the doped structures 126a easily contact with each other in the matrix 124a to form a continuous current path, such that the dummy layer 122a has conductivity and the dummy layer 112a has excessively low light transmittance and excessively high haze, thus affecting the optical transparency and clarity of the non-functional region 120a. In some embodiments, the load capacity per unit area of the doped structures 126a in the dummy layer 122a (non-functional region 120a) is less than the load capacity per unit area of the metal nanowires 116a in the conductive layer 112a (functional region 110a), such that the dummy layer 122a has higher electrical resistivity to ensure that the dummy layer 122a does not have electrical functions (e.g., has no touch sensing and signal transmission functions) and to ensure that the dummy layer 122a has higher light transmittance and lower haze, which enables the non-functional region 120a and the functional region 110a to have a consistent optical performance.

The dummy layer 122a of the present disclosure may have suitable electrical resistivity, light transmittance, and haze, in which the electrical resistivity, light transmittance, and haze of the dummy layer 122a can be respectively regarded as the electrical resistivity, light transmittance, and haze of the non-functional region 120a, and can be respectively referred to as the second electrical resistivity, the second light transmittance, and the second haze in the present disclosure. In some embodiments, the electrical resistivity of the dummy layer 122a may be greater than 50 ops, such that the non-functional region 120a is preferably non-conductive. In some embodiments, the light transmittance of the dummy layer 122a may be greater than 90%, such that the dummy layer 122a has better optical transparency. In some embodiments, the haze of the dummy layer 122a may be less than 2%, such that the dummy layer 122a has better optical clarity. It is understood that the light transmittance of the dummy layer 122a refers to a luminous flux percentage of visible light (light with a wavelength between 400 nm and 700 nm) passing through the dummy layer 122a to visible light incident on the dummy layer 122a, while the haze of the dummy layer 122a refers to a luminous flux percentage of visible light scattered after being incident on the dummy layer 122a to visible light incident on the dummy layer 122a.

Since the functional region 110a and the non-functional region 120a of the present disclosure are formed by coating in stages (steps), the functional region 110a and the non-functional region 120a can respectively have different materials and load capacities, and the functional region 110a and the non-functional region 120a can respectively have suitable electrical resistivity, light transmittance, and haze, so as to respectively provide suitable electrical and optical properties. Accordingly, the functional region 110a and the non-functional region 120a can have a quite consistent optical performance (e.g., optical transparency and clarity) while having different electrical performances (e.g., conductivity). Specifically, in the optically consistent transparent conductor 100 of the present disclosure, a difference in ratio between the electrical resistivity of the functional region 110a and the electrical resistivity of the non-functional region 120a may be in a range from 5% to 9900%, a difference in ratio between the haze of the functional region 110a and the haze of the non-functional region 120a may be in a range from 2% to 500%, and a difference in ratio between the light transmittance of the functional region 110a and the light transmittance of the non-functional region 120a may be in a range from 0.1% to 15%. In some further embodiments, the difference in ratio between the electrical resistivity of the functional region 110a and the electrical resistivity of the non-functional region 120a may be in a range from 5% to 5000%. It should be understood that the “difference in ratio between A and B” mentioned in this disclosure is defined as |A−B|/A or |B−A|/A, in which A≤B.

For example, since the electrical resistivity of the non-functional region 120a (i.e., the second electrical resistivity) is greater than the electrical resistivity of the functional region 110a (i.e., the first electrical resistivity), the above-mentioned “difference in ratio between the electrical resistivity of the functional region 110a and the electrical resistivity of the non-functional region 120a” refers to the formula represented by |first electrical resistivity-second electrical resistivity|/first electrical resistivity.

On the other hand, based on the physical properties (e.g., the color characteristics) of the materials used in the functional region 110a and the non-functional region 120a, the functional region 110a and the non-functional region 120a may each have a measure of yellowness. It should be understood that the “yellowness of A” mentioned in this disclosure refers to the “degree of yellow color shown by A”, which can be represented by the b* value of A in L*a*b* color space, in which the larger the b* value, the more obvious the “yellow color” is presented by A, that is, the closer the color of A is to yellow. The conductive layer 112a and the dummy layer 122a of the present disclosure may each have suitable yellowness, in which the yellowness of the conductive layer 112a and the dummy layer 122a can be respectively regarded as the yellowness of the functional region 110a and the non-functional region 120 and can be respectively referred to as a first yellowness and a second yellowness in the present disclosure. In some embodiments, the difference in ratio between the first yellowness and the second yellowness may be in a range from 1% to 700%. As such, the yellowness of the functional region 110a and the non-functional region 120a can be separately adjusted, such that the optically consistent transparent conductor 100 has a quite consistent color performance.

Based on the above, since the functional region 110a and the non-functional region 120a can respectively have different materials and load capacities, the difference in ratio of the electrical resistivity, the difference in ratio of the haze, the difference in ratio of the light transmittance, and the difference in ratio of the yellowness can each have a considerable range, so as to be flexibly adjusted and matched with each other according to the requirements of the product. Accordingly, the product requirements of various specifications can be met. For example, when the difference in ratio of the electrical resistivity, the difference in ratio of the haze, the difference in ratio of the light transmittance, and the difference in ratio of the yellowness required for a product of a certain specification are respectively 500%, 300%, 2%, and 25%, the designer can satisfy the product's requirements for the electrical resistivity, haze, light transmittance, and yellowness by making the functional region 110a and the non-functional region 120a have different materials and load capacities thereof. Accordingly, the optically consistent transparent conductor 100 can have a quite consistent optical performance while the functional region 110a and the non-functional region 120a have different electrical performances.

In some embodiments, the width and thickness of the conductive layer 112a can be set to make the functional region 110a have better conductivity. In some embodiments, a width W1 of the conductive layer 112a may be between 2 μm and 50 mm, and a thickness T1 of the conductive layer 112a may be between 10 nm and 10 μm. In detail, when the width W1 of the conductive layer 112a is greater than 50 mm and/or the thickness T1 is greater than 10 μm, it may cause the light transmittance of the conductive layer 112a to be excessively low and the haze of the conductive layer 112a to be excessively high, such that the optical transparency and clarity of the functional region 110a is lower; when the width W1 of the conductive layer 112a is less than 2 μm and/or the thickness T1 is less than 10 nm, it may cause the electrical resistivity of the conductive layer 112a to be excessively high, such that the conductivity of the functional region 110a is lower, and it may also cause inconvenience of a manufacturing process (e.g., difficulties for patterning).

In some embodiments, the width and thickness of the dummy layer 122a can be set to make the non-functional region 120a have better optical transparency and clarity. In some embodiments, a width W2 of the dummy layer 122a may be 2 μm and 50 mm, and a thickness T2 of the dummy layer 122a may be 10 nm and 10 μm. In detail, when the width W2 of the dummy layer 122a is greater than 50 mm, it may cause the width W1 of the conductive layer 112a to be compressed, thus affecting electrical functions of the functional region 110a, and when the thickness T2 of the dummy layer 122a is greater than 10 μm, it may cause the dummy layer 122a to have excessively low light transmittance and excessively high haze, thus affecting the optical transparency and clarity of the non-functional region 120a; when the thickness T2 of the dummy layer 122a is less than 2 μm and/or the thickness T2 is less than 10 nm, it may cause inconvenience of a manufacturing process (e.g., difficulties for patterning).

In some embodiments, the optically consistent transparent conductor 100a may further include a substrate 130a configured to carry the functional region 110a and the non-functional region 120a. In other words, the substrate 130a is configured to carry the conductive layer 112a in the functional region 110a and the dummy layer 122a in the non-functional region 120a. The substrate 130a may be, for example, an optically transparent material, that is, its light transmittance in a visible region is at least greater than 90%, so as to provide good light transmittance to the optically consistent transparent conductor 100a. Specifically, the substrate 130a may include polyethylene terephthalate, cycloolefin polymer, polyimide, or combinations thereof. In some embodiments, the substrate 130a may have a thickness T3 between 15 μm and 150 μm. In detail, when the thickness T3 of the substrate 130a is less than 15 μm, it may result in insufficient carrying strength; when the thickness T3 of the substrate is greater than 150 μm, it may cause the substrate 130a to have an excessively low light transmittance and an excessively high haze, and also cause the optically consistent transparent conductor 100a to have an excessively large overall thickness, thus affecting the appearance of the optically consistent transparent conductor 100a and causing material waste.

In some embodiments, the optically consistent transparent conductor 100a may further include a protective layer 140a disposed on a surface 131a of the substrate 130a configured for carrying the non-functional region 120a and the functional region 110a. The protective layer 140a covers the functional region 110a and the non-functional region 120a and extends between the conductive layer 112a and the dummy layer 122a, such that the conductive layer 112a and the dummy layer 122a are insulated from each other. In some embodiments, the protective layer 140a may be, for example, an insulating material to effectively achieve the effect of electrical insulation. In some embodiments, the protective layer 140a may be, for example, an optically transparent material. That is, a light transmittance of the protective layer 140a in a visible region is at least greater than 90%, so as to provide good light transmittance to the optically consistent transparent conductor 100a. In some embodiments, the protective layer 140a may have a thickness T4 between 0.1 μm and 10 μm. In detail, when the thickness T4 of the protective layer 140a is less than 0.1 μm, it may result in the conductive layer 112a and the dummy layer 122a not being effectively separated, thus affecting electrical functions of the optically consistent transparent conductor 100a; when the thickness T4 of the protective layer 140a is greater than 10 μm, it may cause the protective layer 140a to have excessively low light transmittance and excessively high haze and also cause the optically consistent transparent conductor 100a to have an excessively large thickness, thus affecting the appearance of the optically consistent transparent conductor 100a and causing material waste.

Please refer to Table 1, which specifically presents the haze, light transmittance, and yellowness of the layers used to form the functional region 110a and the non-functional region 120a of the present disclosure (e.g., the layers defining the conductive layer 112a and the dummy layer 122a) under different electrical resistivity (e.g., surface (or sheet) resistivity) through each embodiment. It should be understood that the nanostructures included in the layers of each embodiment in Table 1 are metal nanowires, and the layer of each embodiment is formed on the substrate 130a including polyethylene terephthalate and covered by the protective layer 140a including acrylic resin, in which the thickness T3 of the substrate 130a is 50 μm, and the thickness T4 of the protective layer 140a is 1 μm.

TABLE 1

| | surface | | light | |
|---|---|---|---|---|
| | resistivity | haze | transmittance | yellowness |
| | (ops) | (%) | (%) | (no unit) |
| substrate | | 0.96 | 93.7 | 1.03 |
| substrate and | | 0.62 | 93.7 | 0.61 |
| protective layer | | | | |
| Embodiment 1 | 10 | 3.24 | 87.8 | 4.17 |
| Embodiment 2 | 20 | 2.04 | 90.7 | 2.38 |
| Embodiment 3 | 50 | 1.09 | 92.5 | 1.29 |
| Embodiment 4 | 70 | 0.94 | 92.8 | 1.08 |
| Embodiment 5 | 95 | 0.87 | 92.9 | 1.06 |
| Embodiment 6 | 100 | 0.86 | 93.0 | 1.05 |
| Embodiment 7 | 105 | 0.84 | 93.0 | 0.93 |
| Embodiment 8 | 200 | 0.76 | 93.2 | 0.87 |
| Embodiment 9 | 300 | 0.75 | 93.3 | 0.83 |
| Embodiment 10 | 500 | 0.75 | 93.4 | 0.82 |
| Embodiment 11 | 700 | 0.74 | 93.4 | 0.81 |
| Embodiment 12 | 1000 | 0.65 | 93.5 | 0.65 |

Take Embodiments 5 and 6 in Table 1 as an example, the difference in ratio of electrical resistivity between Embodiments 5 and 6 is about 5% (|100−95|/95=5%), the difference in ratio of haze between Embodiments 5 and 6 is about 1.1% (|0.86−0.87|/0.86=1.1%), the difference in ratio of light transmittance between Embodiments 5 and 6 is about 0.1% (|93.0−92.9|/92.9=0.1%), and the difference in ratio of yellowness between Embodiments 5 and 6 is about 1% (|1.05−1.06|/1.05=1%). Take Embodiments 1 and 11 in Table 1 as another example, the difference in ratio of electrical resistivity between Embodiments 1 and 11 is about 9900% (|1000|10|/10=9900%), the difference in ratio of haze between Embodiments 1 and 11 is about 398% (|3.24−0.65|/0.65=398%), the difference in ratio of light transmittance between Embodiments 1 and 11 is about 6.5% (|93.5−87.8|/87.8=6.5%), and the difference in ratio of yellowness between Embodiments 1 and 11 is about 541.5% (|4.17−0.65|/0.65=541.5%). It can be seen that by selecting suitable materials and their load capacities to form the layers of the Embodiments in Table 1, the difference in ratio of the electrical resistivity, the difference in ratio of the haze, the difference in ratio of the light transmittance, and the difference in ratio of the yellowness can each have a considerable range, such that suitable layers can be selected according to product requirements (e.g., electrical or optical requirements) to form the functional region 110a and non-functional region 120a of the present disclosure. Accordingly, the optically consistent transparent conductor 100a can have a quite consistent optical performance while the functional region 110a and the non-functional region 120a have different electrical performances.

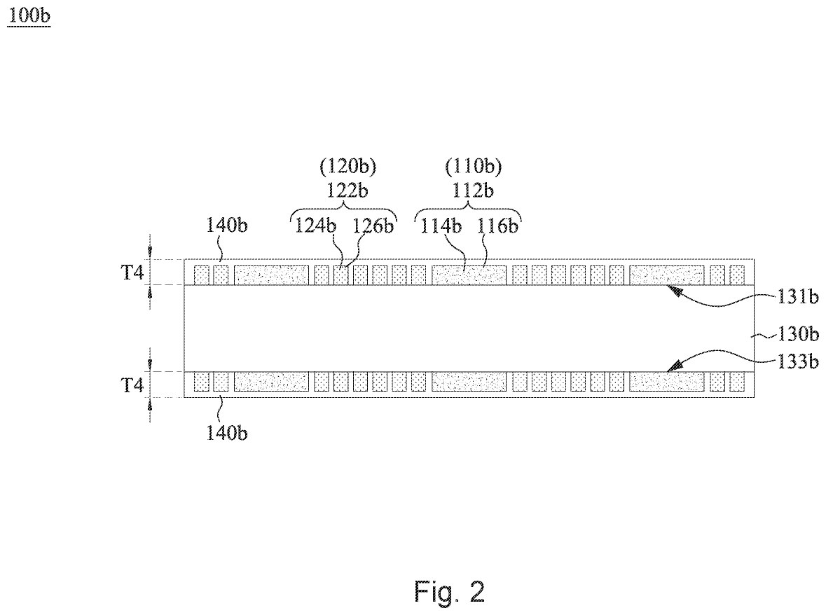

FIG. 2 is a schematic cross-sectional view illustrating an optically consistent transparent conductor 100b according to some other embodiments of the disclosure. It is noted that the optically consistent transparent conductor 100b of FIG. 2 and the optically consistent transparent conductor 100a of FIG. 1 have approximately the same connection relationships, the same materials, and the same advantages of the elements, and will not be described repeatedly herein. Only the differences will be described in detail hereinafter. At least one difference between the optically consistent transparent conductor 100b of FIG. 2 and the optically consistent transparent conductor 100a of FIG. 1 is that the functional region 110b and the non-functional region 120b are both disposed on a first surface 131b and a second surface 133b of a substrate 130b, in which the first surface 131b is facing away from the second surface 133b.

In some embodiments, the functional region 110b and the non-functional region 120b which are disposed on the first surface 131b may be symmetrical with the functional region 110b and the non-functional region 120b which are disposed on the second surface 133b, so as to improve the convenience of the manufacturing process. In other words, a vertical projection on the substrate 130b of the functional region 110b and the non-functional region 120b disposed on the first surface 131b can completely overlap a vertical projection on the substrate 130b of the functional region 110b and the non-functional region 120b disposed on the second surface 133b. In some embodiments, the optically consistent transparent conductor 100b may also include protective layers 140b disposed on the first surface 131b and the second surface 133b and covering the functional region 110b and the non-functional region 120b. In some embodiments, the protective layers 140b disposed on the first surface 131b and the second surface 133b may have the same thickness T4, thereby improving the convenience of the manufacturing process.

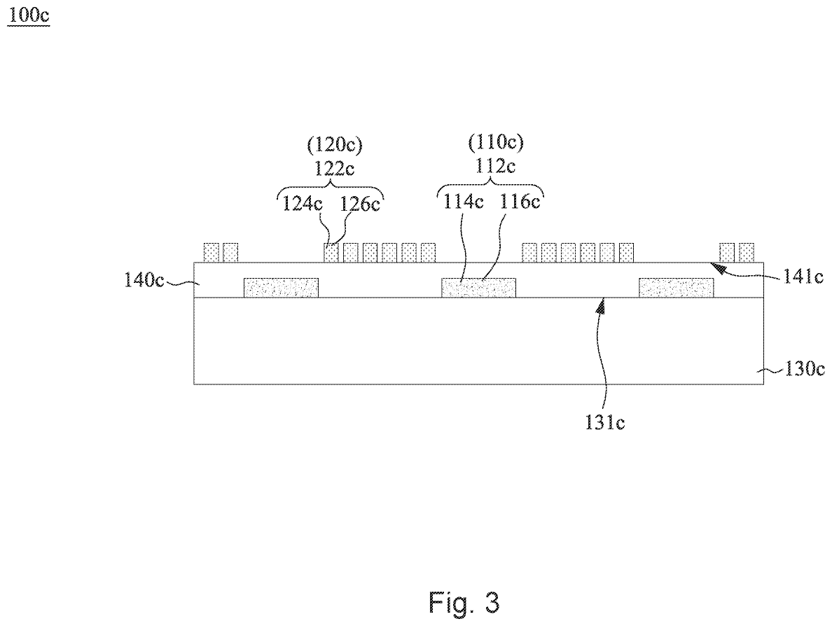

FIG. 3 is a schematic cross-sectional view illustrating an optically consistent transparent conductor 100c according to some other embodiments of the disclosure. It should be noted that the optically consistent transparent conductor 100c of FIG. 3 and the optically consistent transparent conductor 100a of FIG. 1 have approximately the same connection relationships, the same materials, and the same advantages of the elements, and will not be described repeatedly herein. Only the differences will be described in detail hereinafter. At least one difference between the optically consistent transparent conductor 100c of FIG. 3 and the optically consistent transparent conductor 100a of FIG. 1 is that the functional region 110c and the non-functional region 120c are arranged on different horizontal planes. That is, the functional region 110c and the non-functional region 120c are stacked above a substrate 130c in a double-layer structure manner.

In some embodiments, the functional region 110c may be disposed on a first surface 131c (also referred to as a first horizontal plane) of the substrate 130c, while the non-functional region 120c may be disposed on a second surface 141c (also referred to as a second horizontal plane) of the protective layer 140c covering the functional region 110c. In other words, the non-functional region 120c is disposed above the functional region 110c. In some embodiments, the conductive layer 112a located in the functional region 110c and the dummy layer 122a located in the non-functional region 120c may be mutually staggered in a direction perpendicular to an extending plane of the substrate 130c (e.g., the first surface 131c or top surface of the substrate 130c), such that the optically consistent transparent conductor 100c presents the same visual effect as the optically consistent transparent conductor 100a. In other embodiments, the conductive layer 112a located in the functional region 110c and the dummy layer 122a located in the non-functional region 120c may partially overlap in a direction perpendicular to the first horizontal plane and the second horizontal plane, and an overlapping area is less than or equal to 50% of an area of the conductive layer 112a. In detail, when the overlapping area is greater than 50%, the optically consistent transparent conductor 100c may fail to present uniform and consistent visual effects (e.g., consistent optical transparency and optical clarity). In some embodiments, the positions of the functional region 110c and the non-functional region 120c can also be exchanged according to actual requirements, such that the functional region 110c is disposed above the non-functional region 120c. In this case, the optically consistent transparent conductor 100c may further include another protective layer (not shown) which covers and protects the conductive layer 112c located in the functional region 110c.

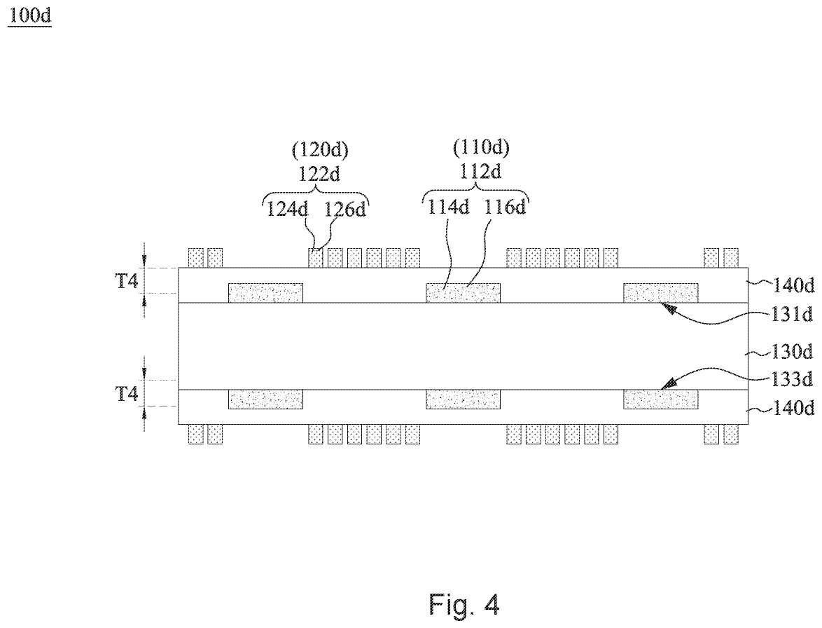

FIG. 4 is a schematic cross-sectional view illustrating an optically consistent transparent conductor 100d according to some other embodiments of the disclosure. It should be noted that the optically consistent transparent conductor 100d of FIG. 4 and the optically consistent transparent conductor 100c of FIG. 3 have approximately the same connection relationships, the same materials, and the same advantages of the elements, and will not be described repeatedly herein. Only the differences will be described in detail hereinafter. At least one difference between the optically consistent transparent conductor 100d of FIG. 4 and the optically consistent transparent conductor 100c of FIG. 3 is that the functional region 110d and the non-functional region 120d are both disposed on a side of a first surface 131d and a side of a second surface 133d of a substrate 130d, in which the first surface 131d is facing away from the second surface 133d.

In some embodiments, the functional region 110d and the non-functional region 120d which are disposed on the side of the first surface 131d may be symmetrical with the functional region 110d and the non-functional region 120d which are disposed on the side of the second surface 133d, so as to improve the convenience of a manufacturing process. In other words, a vertical projection on the substrate 130d of the functional region 110d and the non-functional region 120d disposed on the side of the first surface 131d can completely overlap a vertical projection on the substrate 130d of the functional region 110d and the non-functional region 120d disposed on the side of the second surface 133d. In some embodiments, the optically consistent transparent conductor 100d may also include protective layers 140d disposed on the first surface 131d and the second surface 133d and covering the functional region 110d. In some embodiments, the protective layers 140d disposed on the first surface 131d and the second surface 133d may have the same thickness T4, thereby improving the convenience of a manufacturing process. In some embodiments, the position of the functional region 110d and the non-functional region 120d located on the side of the same surface can be exchanged according to actual requirements, such that the functional region 110d is farther away from the substrate 130d than the non-functional region 120d. When the functional region 110d is farther away from the substrate 130d than the non-functional region 120d, the optically consistent transparent conductor 100d may further include another protective layer (not shown) which covers and protects the conductive layer 112d located in the functional region 110d.

It is noted that the connection relationships, the materials, and the advantages of the elements described above will not be repeated. In the following description, a manufacturing method of the optically consistent transparent conductors 100a to 100d will be described.

### The Manufacturing Method of the Optically Consistent Transparent Conductor 100a

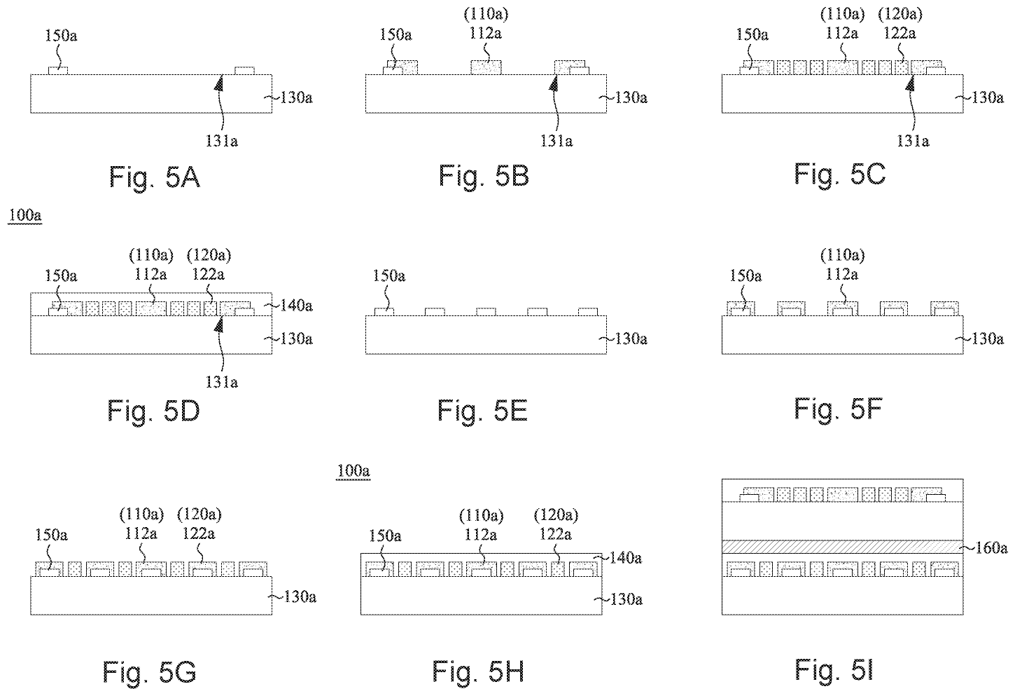

FIGS. 5A to 5I are schematic cross-sectional views illustrating a method for manufacturing the optically consistent transparent conductor 100a of FIG. 1B at different steps.

First, referring to FIG. 5A, in step S10, a substrate 130a is provided, and a conductive circuit 150a is formed by coating on a first surface 131a of the substrate 130a through flexographic printing. In some embodiments, the conductive circuit 150a is formed in a non-visible region of the substrate 130a.

Next, referring to FIG. 5B, in step S12, a conductive layer 112a is formed by coating on the first surface 131a of the substrate 130a through flexographic printing to form a functional region 110a with electrical functions (e.g., touch sensing and signal transmission functions). In some embodiments, a solution (also referred to as a first solution) including metal nanowires is coated onto the first surface 131a of the substrate 130a and dried to form the conductive layer 112a. In some embodiments, the first solution may be coated to be in contact with the conductive circuit 150a, such that the conductive layer 112a formed after drying is connected to the conductive circuit 150a to implement mutual electrical connection. In some embodiments, a portion of the first solution may be coated on the conductive circuit 150a, such that the conductive layer 112a formed after drying partially overlaps the conductive circuit 150a. That is, some portions of the conductive layer 112a formed after drying are in direct contact with the substrate 130a, while other portions of the conductive layer 112a formed after drying are in direct contact with the conductive circuit 150a. In some embodiments, the drying may be performed at a temperature of 50° C. to 150° C. In detail, when the drying is performed at a temperature below 50° C., the first solution may not be cured completely due to an excessively low temperature, thus affecting electrical functions of the functional region 110a and subsequent manufacturing steps; when the drying is performed above 150° C., the substrate 130a may be bent and deformed, thus affecting the yield of products and subsequent manufacturing steps.

In some embodiments, based on a total weight of the first solution, the first solution may have a solid content between 0.01 wt % and 2.00 wt %, that is, the content of metal nanowires in the first solution may be between 0.01 wt % and 2.00 wt %. In this way, the first solution can have an appropriate viscosity to facilitate coating, and the conductive layer 112a formed by drying the first solution has higher conductivity, optical transparency, and clarity. In detail, when the solid content of the first solution is less than 0.01 wt %, it may cause the first solution to have excessively high fluidity and easily spread quickly after coating, such that the coating range cannot be effectively controlled, and the conductivity of the conductive layer 112a may be excessively low; when the solid content of the first solution is greater than 2.00 wt %, it may cause the first solution to be excessively viscous and difficult to coat, and may cause the optical transparency and clarity of the conductive layer 112a to be excessively low. In some embodiments, the viscosity of the first solution may be between 50 cp and 2000 cp to facilitate coating. In detail, when the viscosity of the first solution is less than 50 cp, it may cause the first solution to have excessively high fluidity and easily spread quickly after coating, such that the coating range cannot be effectively controlled; when the viscosity of the first solution is greater than 2000 cp, it may cause the first solution to be excessively viscous and difficult to coat.

Then, referring to FIG. 5C, in step S14, a dummy layer 122a is formed by coating on the first surface 131a of the substrate 130a through flexographic printing to form a non-functional region 120a without electrical functions (e.g., no touch sensing and signal transmission functions). In some embodiments, a solution (also referred to as a second solution) including the foregoing doped structure may be coated onto the first surface 131a of the substrate 130a and dried to form the dummy layer 122a. In some embodiments, the second solution may be coated in a gap between the conductive layers 112a without contacting the conductive layers 112a, such that the dummy layer 122a formed after drying is separated from the conductive layer 112a. In some embodiments, the drying may be performed at a temperature of 50° C. to 150° C. In detail, when the drying is performed at a temperature below 50° C., the second solution may not be cured completely due to an excessively low temperature, thus affecting optical auxiliary functions of the functional region 110a and subsequent manufacturing steps; when the drying is performed above 150° C., the substrate 130a may be bent and deformed, thus affecting the yield of products and subsequent manufacturing steps.

In some embodiments, based on a total weight of the second solution, the second solution may have a solid content between 0.01 wt % and 2.00 wt %, that is, the content of the doped structures in the second solution may be between 0.01 wt % to 2.00 wt %. In this way, the second solution can have an appropriate viscosity to facilitate coating, and the dummy layer 122a formed by drying the second solution does not have conductivity but has high optical transparency and clarity. In detail, when the solid content of the second solution is less than 0.01 wt %, it may cause the second solution to have excessively high fluidity and easily spread quickly after coating, such that the coating range cannot be effectively controlled; when the solid content of the second solution is greater than 2.00 wt %, it may cause the second solution to be excessively viscous and difficult to coat and may cause the optical transparency and clarity of the dummy layer 122a to be excessively low. In addition, since the solid content of the second solution may be smaller than the solid content of the first solution, the conductive layer 112a and the dummy layer 122a formed after drying may have completely different electrical resistivity and conductivity (e.g., the conductive layer 112a may have high conductivity while the dummy layer 122a may not have conductivity). In some embodiments, the viscosity of the second solution may be between 50 cp and 2000 cp, thus facilitating coating. In detail, when the viscosity of the second solution is less than 50 cp, it may cause the second solution to have excessively high fluidity and easily spread quickly after coating, such that the coating range cannot be effectively controlled; when the viscosity of the second solution is greater than 2000 cp, it may cause the second solution to be excessively viscous and difficult to coat.

In the foregoing step, since the functional region 110a and the non-functional region 120a are formed by coating multiple times, the two regions can have different materials and load capacities, thus avoiding mutual restraint between the two regions in electrical and optical properties. In other words, the foregoing steps can make the functional region 110a and the non-functional region 120a be provided with a quite consistent optical performance while having different electrical performances.

Then, referring to FIG. 5D, in step S16, a protective layer 140a is formed by coating on the first surface 131a of the substrate 130a through flexographic printing, so as to cover and protect the conductive circuit 150a, the conductive layer 112a in the functional region 110a, and the dummy layer 122a in the non-functional region 120a. In some embodiments, the protective layer 140a further extends between the conductive circuit 150a, the conductive layer 112a, and the dummy layer 122a, thereby ensuring that the conductive circuit 150a, the conductive layer 112a, and the dummy layer 122a are electrically insulated from each other. After this step, the optically consistent transparent conductor 100a of the present disclosure can be formed.

Next, in FIGS. 5E to 5H, steps S10 to S16 are repeated to form another optically consistent transparent conductor 100a of the present disclosure. In some embodiments, the conductive circuit 150a formed in FIG. 5E, the conductive layer 112a formed in FIG. 5F, and the dummy layer 122a formed in FIG. 5G may have different patterns from the conductive circuit 150a formed in FIG. 5A, the conductive layer 112a formed in FIG. 5B, and the dummy layer 122a formed in FIG. 5C, respectively.

Then, referring to FIG. 5I, in step S18, the optically consistent transparent conductor 100a of FIG. 5A is disposed above the optically consistent transparent conductor 100a of FIG. 5H. In some embodiments, two optically consistent transparent conductors 100a can be bonded to each other through an adhesive layer 160a. In some embodiments, the adhesive layer 160a may be, for example, an optically transparent adhesive with high light transmittance. After this step, a double-layer single-sided transparent conductor including two optically consistent transparent conductors 100a can be formed.

### The Manufacturing Method of the Optically Consistent Transparent Conductor 100b

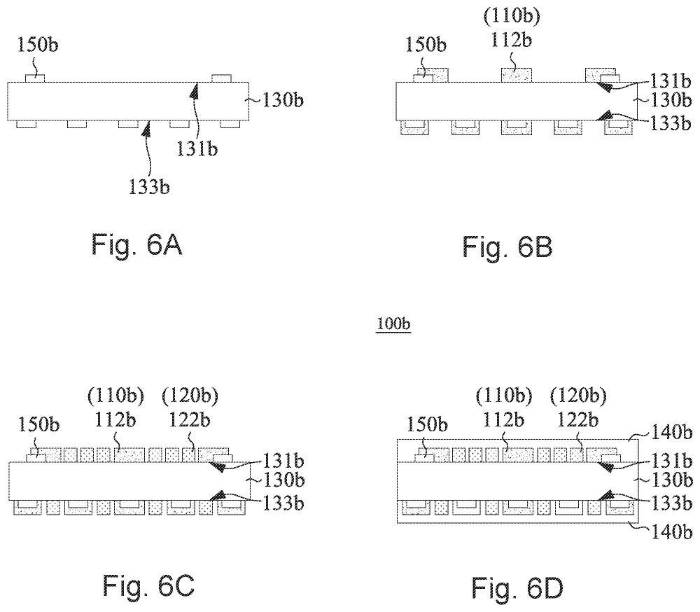

FIGS. 6A to 6D are schematic cross-sectional views illustrating a method for manufacturing the optically consistent transparent conductor 100b of FIG. 2 at different steps.

In FIGS. 6A to 6D, steps S10 to S16 are repeated on the first surface 131b and the second surface 133b of the substrate 130b facing away from each other. In detail, in FIG. 6A, the conductive circuits 150b are sequentially or simultaneously formed on the first surface 131b and the second surface 133b of the substrate 130b; in FIG. 6B, the conductive layers 112b are sequentially or simultaneously formed on the first surface 131b and the second surface 133b of the substrate 130b; in FIG. 6C, the dummy layers 122a are sequentially or simultaneously formed on the first surface 131b and the second surface 133b of the substrate 130b; and in FIG. 6D, the protective layers 140b are sequentially or simultaneously formed on the first surface 131b and the second surface 133b of the substrate 130b. In some embodiments, the conductive circuits 150b, the conductive layers 112b, and the dummy layers 122b formed on the opposite surfaces may have different patterns, respectively. Upon completion of the foregoing steps, the optically consistent transparent conductor 100b of the present disclosure, which is a single-layer double-sided transparent conductor, can be formed.

### The Manufacturing Method of the Optically Consistent Transparent Conductor 100c

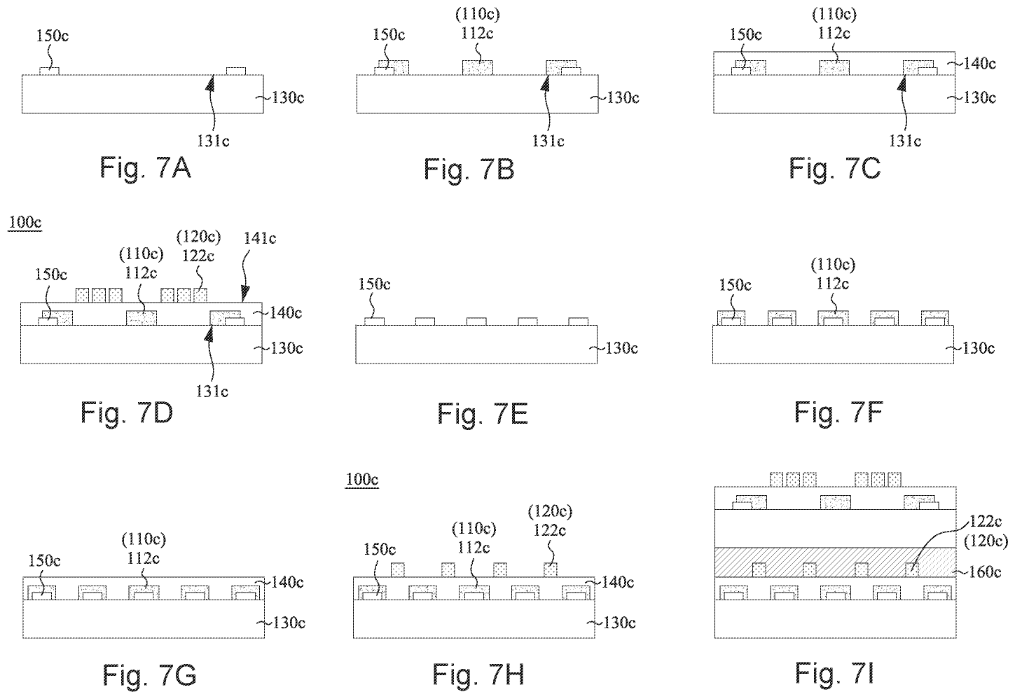

FIGS. 7A to 7I are schematic cross-sectional views illustrating a method for manufacturing the optically consistent transparent conductor 100c of FIG. 3 at different steps.

First, referring to FIG. 7A, in step S20, a substrate 130c is provided, and a conductive circuit 150c is formed by coating on a first surface 131c of the substrate 130c through flexographic printing. In some embodiments, the conductive circuit 150c is formed in a non-visible region of the substrate 130c.

Next, referring to FIG. 7B, in step S22, a conductive layer 112c is formed by coating on the first surface 131c (also referred to as a first horizontal surface) of the substrate 130c through flexographic printing to form a functional region 110c with electrical functions (e.g., touch sensing and signal transmission functions). In some embodiments, a solution (also referred to as a first solution) including metal nanowires can be coated onto the first surface 131c of the substrate 130c and dried to form the conductive layer 112c. In some embodiments, the first solution may be coated to be in contact with the conductive circuit 150c, such that the conductive layer 112c formed after drying is connected to the conductive circuit 150c to implement mutual electrical connection. In some embodiments, a portion of the first solution may be coated onto the conductive circuit 150c, such that the conductive layer 112c formed after drying partially overlaps the conductive circuit 150c. That is, some portions of the conductive layer 112c formed after drying are in direct contact with the substrate 130c, while other portions of the conductive layer 112c formed after drying are in direct contact with the conductive circuit 150c. In some embodiments, the drying may be performed at a temperature of 50° C. to 150° C. In detail, when the drying is performed at a temperature below 50° C., the first solution may not be cured completely due an excessively low temperature, thus affecting electrical functions of the functional region 110c and subsequent manufacturing steps; when the drying is performed above 150° C., the substrate 130c may be bent and deformed due to an excessively high temperature, thus affecting the yield of products and subsequent manufacturing steps. It should be understood that various properties (e.g., the solid content or viscosity) of the first solution have been previously described in detail, and thus will not be repeated hereinafter.

Then, referring to FIG. 7C, in step S24, a protective layer 140c is formed by coating on the first surface 131c of the substrate 130c through flexographic printing, so as to cover and protect the conductive circuit 150c and the conductive layer 112c in the functional region 110c. In some embodiments, the protective layer 140c further extends between the conductive circuit 150c and the conductive layer 112c.

Next, referring to FIG. 7D, in step S26, a dummy layer 122c is formed by coating on a surface 141c of the protective layer 140c facing away from the substrate 130c through flexographic printing to form a non-functional region 120c without electrical functions (e.g., without touch sensing and signal transmission functions). In some embodiments, a solution (also referred to as a second solution) including the foregoing doped structure may be coated onto the surface 141c of the protective layer 140c and dried to form the dummy layer 122c. In some embodiments, the second solution may be coated in a specific position to prevent a pattern formed by the second solution from overlapping the conductive layer 112c below the pattern. That is, the coating position of the second solution and the conductive layer 112c can be staggered from each other in a direction perpendicular to an extending plane of the substrate 130c. In this way, the dummy layer 122c and the conductive layer 112c formed after drying can be staggered from each other in the direction perpendicular to the extending plane of the substrate 130c, such that the optically consistent transparent conductor 100c presents the same visual effect as the optically consistent transparent conductor 100a. In some embodiments, the second solution may be coated in a specific position such that a pattern formed by the second solution partially overlaps the conductive layer 112c positioned below the second solution in the direction perpendicular to the extending plane of the substrate 130c, and the overlapping area is less than or equal to 50% of an area of the conductive layer 112c. In this way, the situation can be avoided where the dummy layer 122c and the conductive layer 112c formed after drying optically interfere with each other in the direction perpendicular to the extending plane of the substrate 130c, which reduces the optical consistency of the optically consistent transparent conductor 100c. In some embodiments, the drying may be performed at a temperature of 50° C. to 150° C. In detail, when the drying is performed at a temperature below 50° C., the second solution may not be cured completely due to an excessively low temperature, thus affecting optical auxiliary functions of the functional region 110c and subsequent manufacturing steps; when the drying is performed above 150° C., the substrate 130c may be bent and deformed, thus affecting the yield of products and subsequent manufacturing steps. It should be understood that various properties (e.g., the solid content or viscosity) of the second solution have been described in detail in the foregoing, and thus will not be repeated hereinafter. After this step, the optically consistent transparent conductor 100c of the present disclosure can be formed.

Next, in FIGS. 7E to 7H, steps S20 to S26 are repeated to form another optically consistent transparent conductor 100c of the present disclosure. In some embodiments, the conductive circuit 150c formed in FIG. 7E, the conductive layer 112c formed in FIG. 7F, and the dummy layer 122c formed in FIG. 7H may have different patterns from the conductive circuit 150c formed in FIG. 7A, the conductive layer 112c formed in FIG. 7B, and the dummy layer 122c formed in FIG. 7D, respectively.

Then, referring to FIG. 7I, in step S28, the optically consistent transparent conductor 100c of FIG. 7A is disposed above the optically consistent transparent conductor 100c of FIG. 7H. In some embodiments, two optically consistent transparent conductors 100c can be bonded to each other through an adhesive layer 160c. In some embodiments, the adhesive layer 160c may further extend between the adjacent dummy layers 122c. In some embodiments, the adhesive layer 160c may be, for example, an optically transparent adhesive with high light transmittance. After this step, a double-layer single-sided transparent conductor including two optically consistent transparent conductors 100c can be formed.

### The Manufacturing Method of the Optically Consistent Transparent Conductor 100d

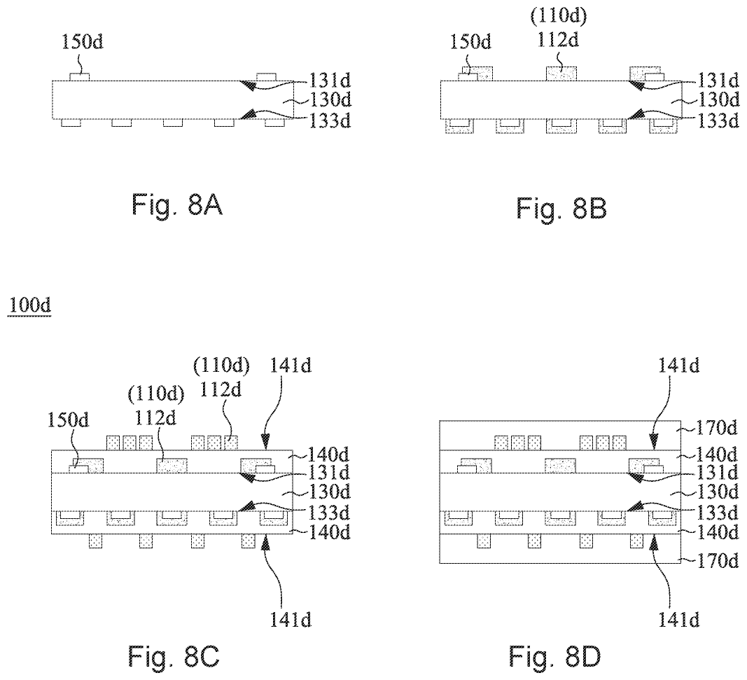

FIGS. 8A to 8D are schematic cross-sectional views illustrating a method for manufacturing the optically consistent transparent conductor 100d of FIG. 4 at different steps.

In FIGS. 8A to 8C, steps S20 to S26 are repeated on a side of the first surface 131d and a side of the second surface 133d of the substrate 130d facing away from each other. In detail, in FIG. 8A, the conductive circuits 150d are sequentially or simultaneously formed on the first surface 131d and the second surface 133d of the substrate 130d; in FIG. 8B, the conductive layers 112d are sequentially or simultaneously formed on the first surface 131d and the second surface 133d of the substrate 130d; in FIG. 8C, the protective layers 140d can be sequentially or simultaneously formed on the first surface 131d and the second surface 133d of the substrate 130d, and the dummy layers 122d are then formed sequentially or simultaneously on surfaces 141d of the protective layers 140d facing away from the substrate 130d; and after this step, an optically consistent transparent conductor 100d of the present disclosure, which is a single-layer double-sided transparent conductor, can be formed. In addition, the conductive circuits 150d, the conductive layers 112d, and the dummy layers 122d formed on the side of the first surface 131d and the side of the second surface 133d of the substrate 130d may have different patterns, respectively.

Then, referring to FIG. 8D, in some embodiments, a protective layer 170d can be selectively formed by coating on the surface 141d of the protective layer 140d farther away from the substrate 130d through flexographic printing. In some embodiments, the protective layer 170d may be substantially the same as the protective layer 140d, such that there may be no interface between the two protective layers.

According to the aforementioned embodiments of the present disclosure, since the optically consistent transparent conductor of the present disclosure is coated multiple times to respectively form a functional region and a non-functional region therein, the functional region and the non-functional region can respectively have different materials and load capacities, so as to respectively provide suitable electrical and optical properties. As such, the electrical and optical properties of the functional region and the non-functional region can be adjusted separately according to the requirements of the product, such that the two regions can have a quite consistent optical performance while having different electrical performances.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

1. An optically consistent transparent conductor, comprising:
a first region comprising a plurality of nanostructures, wherein the first region has a first electrical resistivity and a first haze; and
a second region having a second electrical resistivity and a second haze, wherein a difference in ratio between the first electrical resistivity and the second electrical resistivity is in a range from 5% to 9900%, and a difference in ratio between the first haze and the second haze is in a range from 2% to 500%.

2. The optically consistent transparent conductor of claim 1, wherein the difference in ratio between the first electrical resistivity and the second electrical resistivity is in a range from 5% to 5000%.

3. The optically consistent transparent conductor of claim 1, wherein the first region has a first light transmittance, the second region has a second light transmittance, and a difference in ratio between the first light transmittance and the second light transmittance is in a range from 0.1% to 15%.

4. The optically consistent transparent conductor of claim 1, wherein the first region has a first yellowness, the second region has a second yellowness, and a difference in ratio between the first yellowness and the second yellowness is in a range from 1% to 700%.

5. The optically consistent transparent conductor of claim 1, wherein the nanostructures are metal nanowires.

6. The optically consistent transparent conductor of claim 1, wherein the second region comprises a plurality of doped structures, and the doped structures comprise metal nanowires, carbon nanotubes, graphene, poly(3,4-ethylenedioxythiophene), or combinations thereof.

7. The optically consistent transparent conductor of claim 6, wherein a load capacity per unit area of the nanostructures in the first region is greater than a load capacity per unit area of the doped structures in the second region.

8. The optically consistent transparent conductor of claim 1, wherein the second region comprises at least one dummy structure.

9. The optically consistent transparent conductor of claim 1, wherein the first region has a width between 2 μm and 50 mm, and the second region has a width between 2 μm and 50 mm.

10. The optically consistent transparent conductor of claim 1, wherein the first region has a thickness between 10 nm and 10 μm, and the second region has a thickness between 10 nm and 10 μm.

11. The optically consistent transparent conductor of claim 1, further comprising at least one protective layer covering the first region and the second region, wherein the protective layer comprises an insulating material.

12. The optically consistent transparent conductor of claim 11, wherein the protective layer has a thickness between 0.1 μm and 10 μm.

13. The optically consistent transparent conductor of claim 1, further comprising a substrate carrying the first region and the second region, wherein the substrate comprises polyethylene terephthalate, cycloolefin polymer, polyimide, or combinations thereof.

14. The optically consistent transparent conductor of claim 13, wherein the substrate has a thickness between 15 μm and 150 μm.

15. The optically consistent transparent conductor of claim 1, wherein the first region is located on a first horizontal plane, the second region is located on a second horizontal plane, and the first horizontal plane is different from the second horizontal plane.

16. The optically consistent transparent conductor of claim 15, wherein an overlapping area of the first region and the second region in a vertical direction is less than or equal to 50% of an area of the first region, and the vertical direction is perpendicular to the first horizontal plane and the second horizontal plane.

17. A method for manufacturing an optically consistent transparent conductor, comprising:
coating a substrate to form a first region comprising a plurality of nanostructures, wherein the first region has a first electrical resistivity and a first haze; and
coating the substrate to form a second region, wherein the second region has a second electrical resistivity and a second haze, a difference in ratio between the first electrical resistivity and the second electrical resistivity is in a range from 5% to 9900%, and a difference in ratio between the first haze and the second haze is in a range from 2% to 500%.

18. The method for manufacturing an optically consistent transparent conductor of claim 17, wherein coating the substrate to form the first region comprising the nanostructures comprises:
coating the substrate with a first solution, wherein the first solution has a viscosity between 50 cp and 2000 cp, and based on a total weight of the first solution, the first solution has a solid content between 0.01 wt % and 2.00 wt %.

19. The method for manufacturing an optically consistent transparent conductor of claim 17, wherein coating the substrate to form the second region comprises:
coating the substrate with a second solution, wherein the second solution has a viscosity between 50 cp and 2000 cp, and based on a total weight of the second solution, the second solution has a solid content between 0.01 wt % and 2.00 wt %.

20. The method for manufacturing an optically consistent transparent conductor of claim 17, wherein:
coating the substrate to form the first region comprising the nanostructures comprises forming the first region on a first horizontal plane,
coating the substrate to form the second region comprises forming the second region on a second horizontal plane, and
the first horizontal plane is different from the second horizontal plane.
